(19) United States
(12) Patent Application Publication
(10) Pub. No.: US 2014/0374757 A1
(43) Pub. Date: Dec. 25, 2014

(54) SEMICONDUCTOR MEMORY DEVICE, AND METHOD OF MANUFACTURING THE SAME

(71) Applicant: KABUSHIKI KAISHA TOSHIBA, Tokyo (JP)

(72) Inventors: Misa SUGIMURA, Kanagawa (JP); Yuuji OGAWA, Mie (JP)

(73) Assignee: KABUSHIKI KAISHA TOSHIBA, Tokyo (JP)

(21) Appl. No.: 14/195,771

(22) Filed: Mar. 3, 2014

(30) Foreign Application Priority Data
Jun. 20, 2013 (JP) 2013-130032

(51) Int. Cl. H01L 23/495; H01L 23/00

(52) U.S. Cl. CPC H01L 23/49517; H01L 23/49575; H01L 24/83; H01L 2224/83
USPC 257/48; 257/676; 438/123

(57) ABSTRACT

A circuit board includes a first metal pattern which includes a marking and a first solder resist, a semiconductor memory element mounted on a circuit board, a connection terminal, and a mold resin covering the semiconductor memory element. The semiconductor memory device displays information through the marking which is formed by laser processing on the first metal pattern in areas where the test terminal and the electrode terminal are not provided and the semiconductor memory element is sealed with a mold resin.

### CROSS-REFERENCE TO RELATED APPLICATION

This application is based upon and claims the benefit of priority from Japanese Patent Application No. 2013-130032, filed Jun. 20, 2013, the entire contents of which are incorporated herein by reference.

### FIELD

Embodiments described herein relate generally to a semiconductor memory device, and a method of manufacturing the same.

### BACKGROUND

Some conventional semiconductor memory cards include a nonvolatile semiconductor memory device (for example, a NAND type flash memory) and a controller mounted on one surface of a circuit board, and an electrode pad for reading and writing data provided on the other surface of the circuit board. The semiconductor memory device, the controller, and the electrode pad are connected together by Cu pattern, and both surfaces of the circuit board are covered with a solder resist in order to protect and conceal the Cu pattern.

To mark such a semiconductor memory card, a technique such as ink printing or laser marking has been used. Particularly, for displaying the information of the printed content that is frequently changeable, such as a weekly code (a number indicating which week of the year the product is manufactured) and a lot number, laser marking has generally been used because the printed content may easily be changed.

### DESCRIPTION OF THE DRAWINGS

FIG. 1 is a plan view illustrating an outer shape of a semiconductor memory device according to a first embodiment.

FIG. 2 is a plan view illustrating an outer shape of the semiconductor memory device according to the first embodiment.

FIG. 3 is a cross-sectional view illustrating the inner structure of the semiconductor memory device according to the first embodiment.

FIG. 4 is a plan view illustrating the inner structure of the semiconductor memory device according to the first embodiment.

FIG. 5 is a plan view illustrating the inner structure of the semiconductor memory device according to the first embodiment.

FIG. 6 is a plan view illustrating the inner structure of the semiconductor memory device according to the first embodiment.

FIG. 7 is a flow chart showing a manufacturing process of the semiconductor memory device according to the first embodiment.

FIG. 8 is a cross-sectional view illustrating the manufacturing process of the semiconductor memory device according to the first embodiment.

FIG. 9 is a cross-sectional view illustrating a semiconductor memory device according to a second embodiment.

FIG. 10 is a cross-sectional view illustrating the inner structure of a semiconductor memory device according to a third embodiment.

FIG. 11 is a plan view illustrating the inner structure of the semiconductor memory device according to a third embodiment.

### DETAILED DESCRIPTION

Embodiments provide a semiconductor memory device that is more receptive to laser marking.

In order to solve the above object, a semiconductor memory device according to the embodiment includes a circuit board having a first surface on which a first metal pattern and a first solder resist are deposited and a second surface opposite to the first surface on which a second metal pattern and a second solder resist are deposited, a semiconductor memory element mounted on the first surface, a connection terminal provided on the second surface, a test terminal connected to the first metal pattern and the semiconductor memory element, and an electrode terminal connected to the second metal pattern, the first metal pattern, the semiconductor memory element, and the test terminal. The semiconductor memory device displays information marked by laser processing from the first surface on the first metal pattern in areas where the test terminal and the electrode terminal are not provided and the semiconductor memory element is sealed with a mold resin.

### First Embodiment

A semiconductor memory device 1 according to the following embodiment will be described by using a micro SD card by way of example. Accordingly, the semiconductor memory device 1 in the following description is not limited to a micro SD card and may be other types of memory cards.

A micro SD card has the same features as those of an SD card, except for size. For example, each of the two cards includes a memory chip 10 and a controller chip 9 for controlling the memory chip 10. On the other hand, since the SD card is larger than the micro SD card in size, limitations imposed on the SD card is looser than those imposed on the micro SD card. Namely, the micro SD card is more difficult to be designed than the SD card.

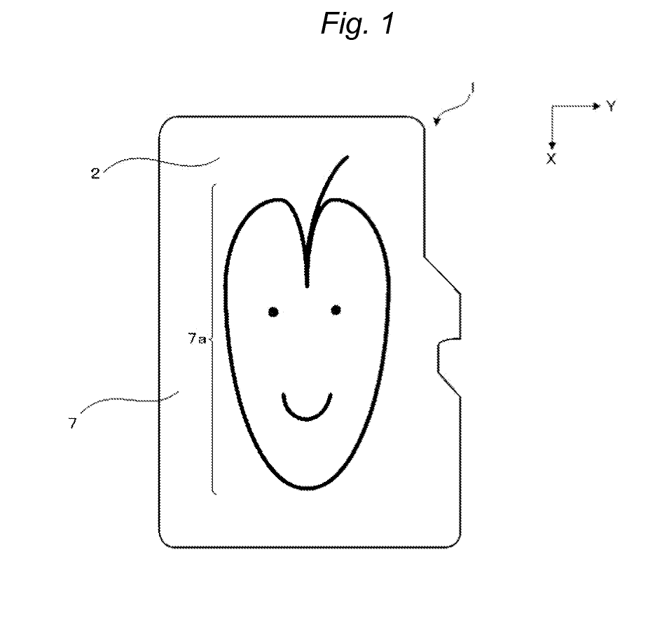

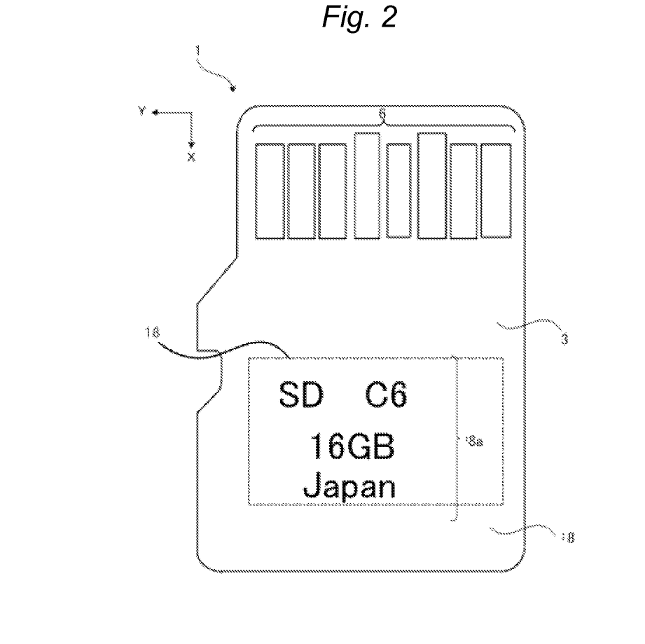

At first, the outer structure of the semiconductor memory device 1 according to the first embodiment will be described. FIGS. 1 and 2 are plan views each illustrating the outer shape of the semiconductor memory device according to the first embodiment.

The semiconductor memory device 1 has a resin surface 2 and a terminal surface 3, which define opposing surfaces. A mounted chip is sealed on the resin surface 2 and a connection terminal 6 is provided on the terminal surface 3.

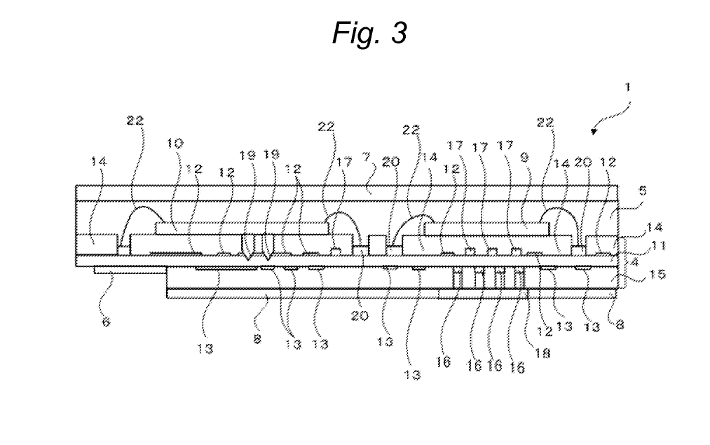

A plurality (eight in the figure) of connection terminals 6 are aligned in parallel in a direction of Y-axis on the terminal surface 3 in the semiconductor memory device 1. The connection terminals 6 are not covered by a mold resin 5 (shown in FIG. 3), so as to electrically connect a host device (outer device) and the semiconductor memory device 1 when the semiconductor memory device 1 is inserted into the host device.

A design layer 7 for showing some information desired by a content maker is formed on the resin surface 2. Here, the design layer is formed by ink printing, and the information includes a letter, a figure, and any other identifiable marking. For example, on the resin surface 2 of the semiconductor memory device 1 where a predetermined content is previously recorded, the design layer 7 may be formed by printing information related to the content. Specifically, in the case of the micro SD memory card where data such as a still image or a moving image of some animation character is recorded in the semiconductor memory device 1, the design layer 7 may be formed by printing an image 7a of the character or the like on the resin surface 2.

Information displayed on the resin surface 2 by the design layer 7 is not limited to an image but may include a character string. The design layer 7 is not limited to a printing layer but it may be a seal to be attached on the resin surface 2. Further, a content maker can print a mark for identification on the design layer 7 according to any arbitrary method (for example, marking by a laser).

As shown in FIG. 1, by providing the design layer 7 on the resin surface 2, information such as a logo mark and an identification code about the semiconductor memory device 1 cannot be printed or marked on the resin surface 2. The micro SD cards are required to display a logo mark 8a or the like according to standards. Therefore, in the embodiment, the information less frequently changeable, such as the logo mark 8a, is displayed on the terminal surface 3. A logo of the SD is printed on the terminal surface 3 as a printing layer 8 by a pad printing or a silk printing. As a business model using the semiconductor memory device 1 where the content is previously recorded, it may be considered that a content maker sells the semiconductor memory device 1 such as the micro SD memory card to a user of a mobile terminal (end user). In this case, even if the content recorded there is the same, by changing the information to be printed on the resin surface 2 as the design layer 7, the value of each semiconductor memory device 1 can change as a commercial product. For example, of some semiconductor memory devices 1 where the same content is recorded, a high rarity card (rare card) can be created by printing a different image on the design layer 7, which enhances the end user's willingness to buy the card as a collector's item or as an investment.

The color of the design layer 7 and the printing layer 8 is not limited to black. The color of the package may be, for example, red, yellow, green, blue, or white.

Next, the internal portion of the semiconductor memory device 1 according to the first embodiment will be described. FIG. 3 is a cross-sectional view illustrating the inner structure of the semiconductor memory device 1 according to the first embodiment.

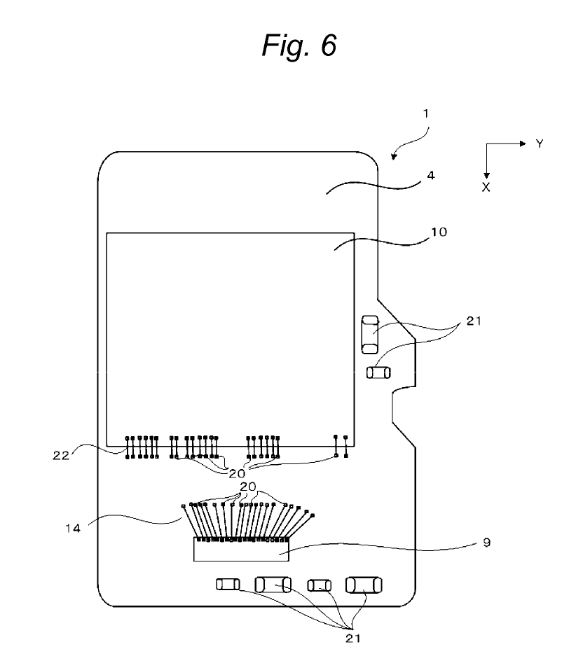

As shown in FIGS. 3 and 6, the semiconductor memory device 1 includes a mold resin 5, the memory chip 10, a circuit board 4, the controller chip 9, and a receiving portion 21, which is, for example, a resistor, a capacitor, or an inductor. The mold resin 5 is formed of an insulation material, to cover and seal the circuit board 4.

At first, the circuit board 4 will be described. The circuit board 4 includes, for example, a core material 11, first and second Cu patterns 12 and 13, and first and second solder resists 14 and 15. The core material 11 is, for example, a glass epoxy substrate; the first Cu pattern 12 is provided on the resin surface 2 and the second Cu pattern 13 is provided on the terminal surface 3.

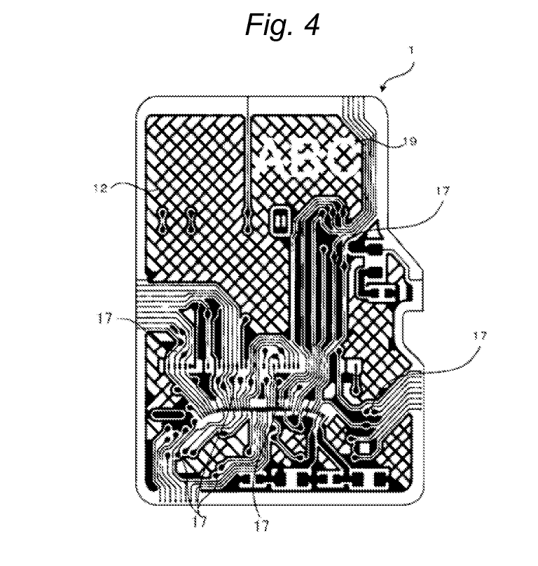

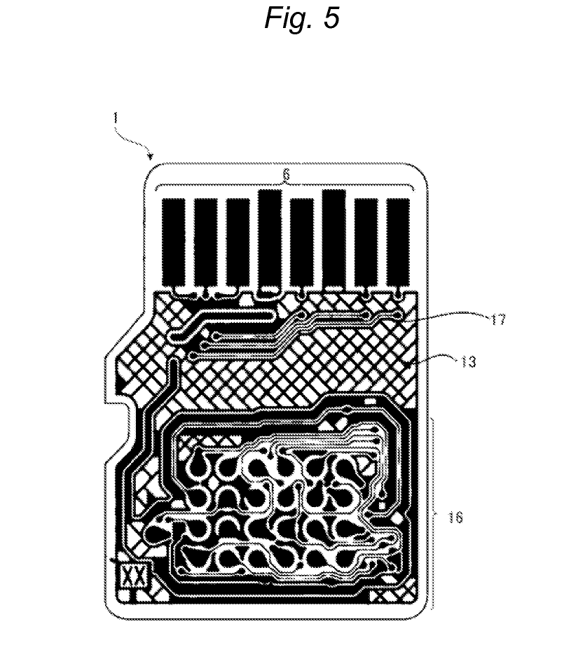

FIGS. 4 and 5 are plan views each illustrating the inner structure of the semiconductor memory device 1 according to the first embodiment. The first and second Cu patterns 12 and 13 have a pattern structure as shown in FIGS. 5 and 6 and are connected to a test terminal 16 and an electrode terminal 17.

A test terminal 16 is covered and sealed with a mask label 18, not exposed in a normal state. A test terminal 16 may be covered and sealed with solder resist. In order to analyze the cause of a failure occurring in the micro SD memory card, the mask label 18 is peeled off to expose the test terminal 16 solely for testing the semiconductor memory device 1.

Returning to FIG. 3, a mark 19 is a bore formed by a laser in an area where electronic components are mounted above the resin surface 2 of the circuit board 4, and the mark 19, penetrating through the first Cu pattern layer 12, is formed in an area excluding the test terminal 16. The bore may be formed by polishing or by peeling off with a cutter blade. The mark is, for example, a letter, figure and any other identifiable marking. In detail, the mark 19 is to show, for example, SD logo, country of origin, and identification code. The mark 19 is not limited to the bore, the mark may be a metal layer whose material is different from the first and second Cu patterns 12 and 13. As shown, the mark 19 is formed in an area excluding the test terminal 16 and the electrode terminal 17. Further, since the mark 19 can be confirmed through X-ray radiation, even if an area for displaying the information such as logo occupies the resin surface 2 and the terminal surface 3, necessary information for production management such as identification code can be displayed. Here, an area for the mark 19 is not limited to the area where the electronic components are mounted. It may be formed in an area where the first Cu pattern 12 is not present.

The first and the second solder resists 14 and 15 are respectively formed on the first and second Cu pattern 12 and 13. The first and the second solder resists 14 and 15 are formed in an area excluding the portion where the connection terminal 6, the test terminal 16, and the connection pad 20 are provided, by masking the portions where the connection terminal 6, the test terminal 16, and the electrode terminal 17 are provided, then applying a thermally-cured or ultraviolet-cured resist ink there, or laminating the core material 11 with a sheet-like molding. For the resist ink, a typical one that contains thermally-cured epoxy-based resin, ultraviolet-cured epoxy-based resin, or ultraviolet-cured acrylate-based resin can be used.

As an example of a dimension of each layer forming the circuit board 4, the thickness of the core material 11 is 100 μm, the thickness of the first and the second Cu pattern 12 and 13 is 12 to 25 μm, the thickness from the surface of the core material 11 to the surfaces of the first and the second solder resists 14 and 15 is 50 μm, the thickness of the first and the second solder resists 14 and 15 on the first and the second Cu pattern 12 and 13 is 25 to 38 μm. These values are by way of example and the disclosure is not limited thereto.

The structure on the circuit board 4 will be described. FIG. 6 is a plan view illustrating the inner structure of the semiconductor memory device 1 according to the first embodiment. In the circuit board 4, the memory chip 10, the controller chip 9, and the receiving portion 21 are mounted on the resin surface 2 and electrically connected together by the electrode terminal 17, the test terminal 16, and the first and the second Cu pattern 12 and 13.

As the memory chip 10, any memory chip may be used; specifically, a NAND typed flash memory chip of any type can be used. Further, a plurality of connection pads 20 electrically connected to the circuits within the memory chip 10 are formed on the top surface of the memory chip 10, and conductive bonding wires 22 connect the connection pads 20 on the circuit board 4.

The controller chip 9 is to control the operation of the memory chip 10. Specifically, according to a command from the outside, the chip 9 writes and reads data in and from the memory chip 10, erases the data of the memory chip 10, and controls the recorded state of the data in the memory chip 10. The controller chip 9 may include a host interface, an MPU (micro processing unit), a ROM (read only memory), a RAM (random access memory), and a memory interface. A plurality of connection pads 20 electrically connected to the circuits within the controller chip 9 are connected to the top surface of the controller chip 9 and further connected to the connection terminal 6 through the conductive pattern printed on the circuit board 4.

The second solder resist 15 may be formed also on the test terminal 16 and the test may be performed on the semiconductor memory device 1 after removing the second solder resist 15.

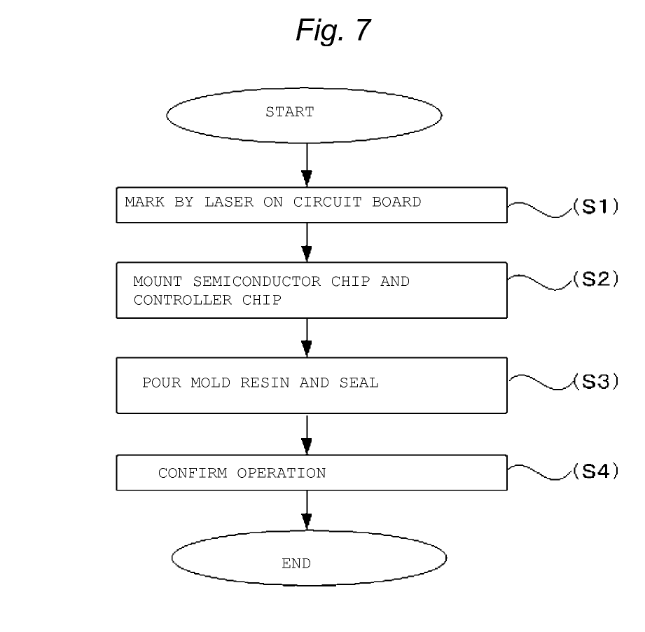

A method of manufacturing the semiconductor memory device 1 according to the first embodiment will be described. FIG. 7 is a flow chart showing the manufacturing process of the semiconductor memory device 1 according to the first embodiment.

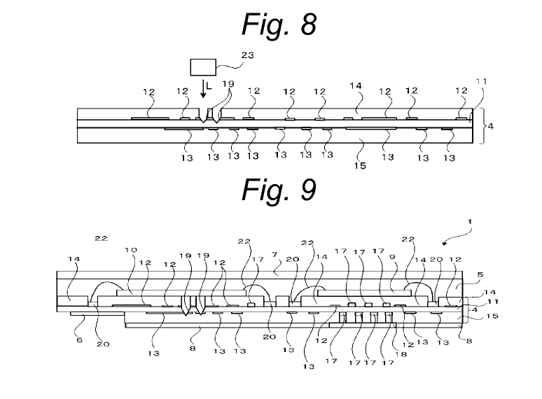

FIG. 8 is a cross-sectional view illustrating the manufacturing process of the semiconductor memory device 1 according to the first embodiment. SD logo, country of origin, and identification code are formed on the terminal surface 3 by a laser oscillator 23 (Step S1). For example, by applying a laser to the terminal surface 3 of the mold resin 5, the surface of the mold resin 5 receiving the laser is peeled off (surface exfoliation), thereby forming the mark (SD logo, country of origin, and identification code) 19.

Then, the controller chip 9, the memory chip 10, and the receiving portion 21 are mounted on a circuit board 4 (Step S2).

Then, by pouring the mold resin 5, the circuit board 4, the lead frame 24, the controller chip 9, the memory chip 10, and the receiving portions 21 are sealed (Step S3).

A test process to be performed just before the shipment of the semiconductor memory device 1 is performed. In the test process, whether the memory chip 10 properly works or not is checked (Step S4). In the test process, whether the semiconductor memory device 1 properly works or not may be checked. Marking by a laser on the mold resin 5 may affect on the memory chip 10 and therefore, this test process is performed after marking by the laser.

The effects of the embodiment will be described. The semiconductor memory device 1 according to the embodiment can avoid a malfunction of the circuits by forming the mark 19 in the first Cu pattern 12 in an area that excludes the test terminal 16 and the electrode terminal 17 when the information is marked by a laser on the area where the electric components are mounted on the circuit board 4. Further, since the electric components are sealed with the mold resin 5 after the mounting thereof, the first and the second Cu pattern 12 and 13 are never exposed, hence to be able to avoid oxidation. Further, by forming the mark 19 before the mounting of the electric components, marking by the laser never damages the electric components and the bonding wires 22.

Further, in the embodiment, the test terminal 16 is provided; therefore, even if a failure occurs in the operation of the circuits, it is possible to detect the cause of the failure. Therefore, the quality of the semiconductor memory device 1 can be managed. In case of an area of the mark 19 being outside the area the electric components formed, the mark 19 may be formed after mounting of the electric components.

### Second Embodiment

In a semiconductor memory device 1 according to a second embodiment, the mark 19 reaches the core material 11 or the second Cu pattern 13 on the terminal surface 3. FIG. 9 is a cross-sectional view illustrating the inner structure of the semiconductor memory device according to the second embodiment. In the embodiment, the mark 19 is formed on the first Cu pattern 12 and the second Cu pattern 13 excluding areas of the test terminal 16 and the electrode terminal 17. In the embodiment, although the mark 19 may reach the second solder resist 15, it does not penetrate through the second solder resist 15. According to this, the first and the second Cu pattern 12 and 13 are neither exposed nor oxidized. Since the mark 19 is formed deeper than that of the first embodiment, information such as letters and illustration can be displayed more definitely.

### Third Embodiment

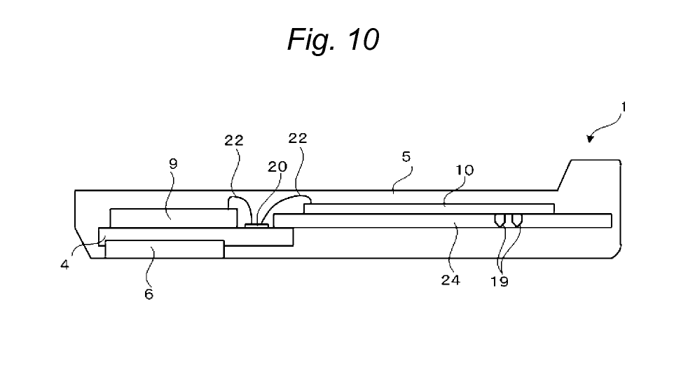

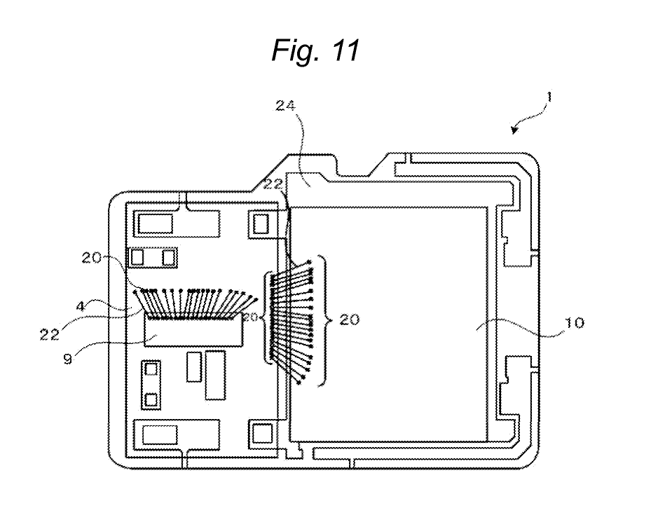

A semiconductor memory device 1 according to a third embodiment uses not only the circuit board 4 but also the lead frame 24. FIG. 10 is a cross-sectional view illustrating the inner structure of the semiconductor memory device according to the third embodiment. FIG. 11 is a plan view illustrating the inner structure of the semiconductor memory device according to the third embodiment.

The lead frame 24 is, for example, a metal plate. On the lead frame 24, the memory chip 10 is mounted through a connection layer (not shown). The lead frame 24 is adhered to the circuit board 4 through the connection layer (not shown).

The controller chip 9 is mounted in the circuit board 4 through the connection layer (not shown). The connection terminal 6 is formed on the side opposite to the surface where the controller chip 9 is provided.

As shown, the mark 19 is formed in the lead frame 24. Since the lead frame 24 includes neither terminal nor circuit for the test terminal 16 and the electrode terminal 17, even if the laser penetrates into the lead frame 24, no failure occurs in the circuits. Therefore, the mark can be formed in a wider area than in the first and the second embodiments. The mark 19 can be formed from any side: from the resin surface 2 or the terminal surface 3. The mark 19 may be formed in the area where the electric components are not mounted or on the circuit board 4.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a circuit board including a first metal pattern which includes a marking and a first solder resist;
a semiconductor memory element mounted on a circuit board;
a connection terminal; and
a mold resin covering the semiconductor memory element.

2. The device according to claim 1, further comprising:
a test terminal connected to the first metal pattern and the semiconductor memory element; and
an electrode terminal connected to the second metal pattern, the first metal pattern, the semiconductor memory element, and the test terminal,
wherein the marking is provided outside the region where the test terminal and the electrode terminal are provided.

3. The device according to claim 1, wherein
the marking is formed by laser processing.

4. The device according to claim 1, wherein
the marking penetrates into a core material of the circuit board.

5. The device according to claim 1, further comprising:
a second metal pattern on the first pattern and a second solder resist are deposited,
the marking penetrates into a core material of the circuit board and the second metal pattern.

6. The device according to claim 1, wherein
the marking includes a production number.

7. The device according to claim 1, wherein
the first metal pattern is Cu pattern.

8. The device according to claim 1, further comprising:
a mask that covers the test terminal.

9. The device according to claim 1, wherein the mold resin covers the entire first metal pattern and the entire second metal pattern except to expose the connection terminal.

10. A semiconductor memory device comprising:
a lead frame on which a semiconductor memory chip is mounted, on which a memory controller chip for the semiconductor memory chip is mounted, and on which an external connection terminal is formed, wherein the memory controller chip and the semiconductor memory chip are on the same side of the lead frame and the external connection terminal is on an opposite side of the lead frame;
laser markings formed on the lead frame; and
a mold resin covering the semiconductor memory chip, the memory controller chip, and the laser markings.

11. The device according to claim 10, wherein the laser markings are formed through the lead flame on a same side on which is the memory controller chip and the semiconductor memory chip are mounted.

12. The device according to claim 10, wherein the laser markings are formed directly on the lead flame opposite a side on which is the memory controller chip and the semiconductor memory chip are mounted.

13. The device according to claim 10, wherein
the laser marking includes a production number.

14. A method of manufacturing a semiconductor memory device comprising:
laser marking a circuit board having metal pattern formed thereon;
mounting an electric component and forming a test terminal on the circuit board;
sealing the electric component onto the circuit board with a mold resin; and
confirming a defect of the electric component using the test terminal.

15. The method of claim 14, wherein the circuit board has opposing first and second surfaces, and metal pattern is formed on both the first and second surfaces.

16. The method of claim 15, wherein the mold resin seals the metal pattern formed on both the first and second surfaces.

17. The method of claim 15, wherein the laser marking is carried out on the first surface.

18. The method of claim 17, wherein the laser marking is carried out to penetrate a core of the circuit board.

19. The method of claim 17, wherein the laser marking is carried out to penetrate a core of the circuit board and the metal pattern formed on the second surface of the circuit board.

20. The method according to claim 14, further comprising:
peeling off a mask that covers the test terminal prior to confirming the defect of the electric component using the test terminal.
